(19) United States
(12) Patent Application Publication
(10) Pub. No.: US 2014/0174501 A1
(43) Pub. Date: Jun. 26, 2014

(54) ENEGRY CONVERSION DEVICE AND METHOD

(71) Applicant: Alfred JOST, Mesa, AZ (US)

(72) Inventor: Alfred JOST, Mesa, AZ (US)

(21) Appl. No.: 14/195,448

(22) Filed: Mar. 3, 2014

Related U.S. Application Data
(63) Continuation-in-part of application No. 14/126,958, filed on Dec. 17, 2013.
(60) Provisional application No. 61/501,211, filed on Jun. 25, 2011.

(51) Int. Cl. H01L 31/052; H01L 31/0525

(52) U.S. Cl. CPC H01L 31/0524; H01L 31/058
USPC 136/246; 136/259; 136/253; 438/65

(57) ABSTRACT

An energy conversion device includes a holographic lens arranged between a glass slab and the first solar cell. The holographic lens is configured to concentrate a portion of a first component of impinging electromagnetic radiation onto the first solar cell and direct a portion of a second component of the electromagnetic radiation away from the first solar cell. The first solar cell is a back contact solar cell configured to convert the first component of the electromagnetic radiation into electrical energy.

### TECHNICAL FIELD

The present disclosure generally relates to a converting electromagnetic radiation into electrical energy, and more particularly relates to the use of solar panels or modules to generate electricity from light energy.

### BACKGROUND

In the field of solar energy, the principle of converting solar radiation into electrical current has been known and used for at more than fifty years. This conversion of light energy into electrical current has been and remains enabled through the use of solar cells that include silicon, conventionally monocrystalline or multicrystalline silicon. The power of these solar cells is relatively low, however, as they only convert a limited spectrum of impinging radiation into electrical current.

Great success has been achieved in recent years with high power photovoltaic cells made of high-quality semiconductor connections (III-IV semiconductor material) such as gallium arsenide to accomplish significantly higher efficiency with about 40% conversion of the solar radiation. This is largely accomplished by concentrating sunlight onto a very small surface area. More particularly, it is a common practice to gather and concentrate sunlight reaching a given photovoltaic cell so that such extremely large areas of semiconductor material need not be employed as would necessarily be the case without such a gathering and concentrating system. Common past gathering systems included optical systems in which lens systems concentrated light and focused it on a given photovoltaic cell. A plurality of solar units allows for the economical use of a photovoltaic system of this type.

However, such a lens system, utilized to impinge sunlight directly on solar cells, was and is relatively expensive and large. Conventional systems predominantly work by incorporating relatively large Fresnel lenses with a relatively large focal length, and this in turn produces modules that are quite thick. These large structures result in solar power units that are very heavy.

Accordingly, it is desirable to provide an energy conversion device or solar module that is able to utilize a large range of wavelengths of light and in turn have improved overall efficiency. In addition, it is desirable to provide an energy conversion device that incorporates fewer and smaller components in order to reduce the module's size and manufacturing costs. Furthermore, other desirable features and characteristics of the present disclosure will become apparent from the subsequent detailed description of the disclosure and the appended claims, taken in conjunction with the accompanying drawings and this background of the disclosure.

### SUMMARY

In one example, an energy conversion device is provided. The energy conversion device includes a holographic lens arranged between a glass slab and the first solar cell. The holographic lens is configured to concentrate a portion of a first component of impinging electromagnetic radiation onto the first solar cell and direct a portion of a second component of the electromagnetic radiation away from the first solar cell. The first solar cell is a back contact solar cell configured to convert the first component of the electromagnetic radiation into electrical energy.

A method of making an energy conversion device is also provided. According to the method, a hologram is roll printed directly onto a glass slab in a pattern that forms a holographic lens. The holographic lens is arranged between the glass slab and a first solar cell. The first solar cell is arranged such that at least one solar cell stripe of the first solar cell is arranged between the holographic lens and an electrical connector, the electrical connector being electrically connected to the at least one solar cell stripe.

### BRIEF DESCRIPTION OF THE DRAWINGS

Exemplary descriptions of the solar module or energy conversion device and methods of producing an energy conversion device will be apparent from the following description and the drawings appended hereto, wherein like numerals denote like elements.

FIG. 1 is a schematic diagram representing the manner by which desirable wavelengths of sunlight are focused with high efficiency onto a solar cell according to an exemplary embodiment.

FIG. 2 is a schematic diagram representing the manner by which undesirable wavelengths of sunlight are focused so they do not impinge onto a solar cell according to another exemplary embodiment.

FIG. 3 is a schematic diagram representing the manner by which desirable and undesirable wavelengths of sunlight are respectively focused with high efficiency onto a solar cell, or focused away from a solar cell and reflected away from the energy conversion device according to an embodiment.

FIG. 4 is a schematic diagram representing the manner by which some undesirable wavelengths of sunlight are transformed to desirable wavelengths of light, and then the remaining wavelengths of light are focused with high efficiency onto different solar cells according to their wavelengths.

FIG. 5 is a schematic diagram representing the manner by which desirable wavelengths of sunlight are focused with high efficiency onto a metal wrap through (MWT) solar cell according to an exemplary embodiment.

FIG. 6 is a schematic diagram representing the manner by which desirable wavelengths of sunlight are focused with high efficiency onto an interdigitated back contact solar cell (IBC).

### DETAILED DESCRIPTION

The following detailed description of the disclosure is merely exemplary in nature and is not intended to be limiting of the energy conversion device or the application and uses of the solar module. Furthermore, there is no intention to be bound by any theory presented in the preceding background or the following detailed description.

In this description, a solar panel and a solar module are interchangeable terms, both being defined as a structure that includes a plurality of solar cells, with the wattage produced being directly proportionally related to the number of solar cells included in the solar module. The solar module also includes a frame, strings that connect the solar cells, a back sheet and a glass slab.

One embodiment is directed to a solar module that includes solar cells with which electrical current is produced by the concentration of light using a lens, in close proximity with the solar cells, that includes silicon or another appropriate semiconductor material. The optical lens is a unique holographic element that function as a lens and is adapted to selectively concentrate, deflect, and focus different components of the solar spectrum, each different light component being treated differently according to the wavelengths of light that are included in that light component.

As will be discussed hereinafter, the novel holographic deflecting lens and its ability to concentrate, focus, and deflect different wavelengths of light in a predetermined manner enables the use of a minimal amount of silicon and other semiconductor material. In fact, a reduction of up to 90% compared to conventional solar panels is enabled by the present disclosure, while producing high amounts of electrical energy. The efficient use of photovoltaic cells allows for production of conventionally sized solar modules that require significantly less semiconductor material.

Furthermore, by employing the new holographic deflecting lens as a means for producing electrical energy from solar radiation, the percentage of the solar radiation that is used to generate electrical energy is greatly improved. Because the lens is able to concentrate, focus, and deflect different light components for different purposes, efficiencies of up to 92% of all solar radiation being converted to electricity using the solar module of the present disclosure are realized.

Additionally, as will be seen in conjunction with the figures, the novel holographic deflecting lens makes possible a solar module in which a very small distance is needed between the lens and the silicon or other semiconductor material. This in turn imparts a very small overall module height and cost friendly production. Consequently, compared to traditional solar panels, a significantly reduced cost of constructing and transporting is achieved.

There is also the advantage that the solar modules can be used on the standard single axis tracking system. Concentrator solar modules generally track in two directions, the first direction being daylight, or movement of the sun, and the second direction being the seasonal or summer-winter position of the sun. The solar module of the present disclosure includes a holographic deflecting lens that adapts to the seasonal or summer-winter variance. Accordingly, only the daylight, or movement of the sun, needs to be tracked to optimize electricity output.

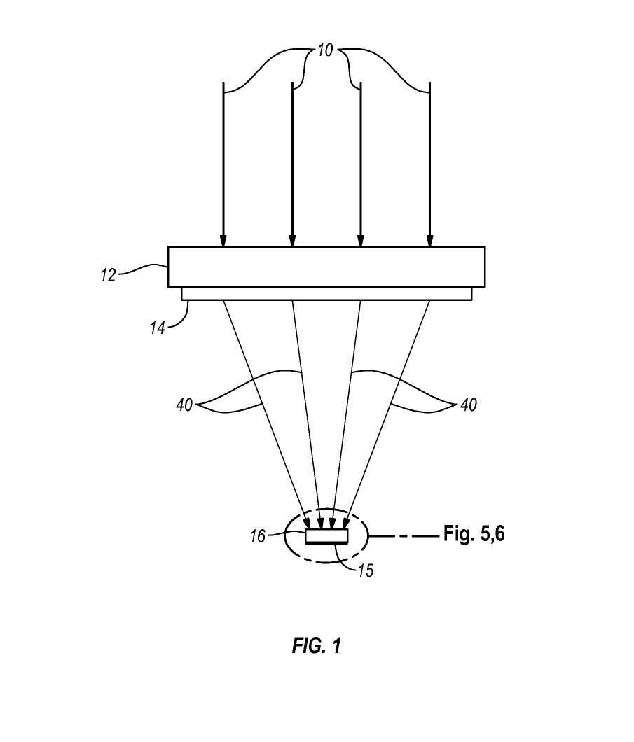

Turning now to FIG. 1, a schematic diagram is used to depict the manner by which desirable wavelengths 40 of sunlight 10 are focused with high efficiency onto a back contact solar cell 16 in a solar module according to an exemplary embodiment of the present disclosure. As depicted in FIG. 1, a sunlight component of desirable wavelengths 40, i.e. light in the visible wavelengths ranging between about 380 and about 750 nm, preferably between about 500 and about 750 nm, more preferably between 500 and 600 nm, and most preferably between 510 and 580 nm, is bent and deflected when it passes through a holographic deflecting lens 14 that is formed directly on a glass slab 12. The visible sunlight component 10 passes through the glass slab 12, which supports the lens 14. As depicted in the figures, the lens 14 is formed on the interior side of the glass slab 12 instead of the exterior side. Consequently, the glass slab 12 functions as a cover and protection for the lens 12 in the solar module.

The lens 14 is adapted to deflect only the sunlight component of desirable wavelengths 40 in a manner whereby it is concentrated and focused with high efficiency onto a photovoltaic back contact solar cell 16. The back contact solar cell 16 is made of a suitable semiconductor material such as mono- or polycrystalline silicon or silicon with a high purity (at least 99.99999%).

The solar cell 16 is part of an array of stripes of the silicon, or other suitable material, with each stripe having a width of 1 mm to 10 mm. the array of strips are electrically connected by back contact 15, which serves as an electrical contact arranged on a side of the solar cell 16 that is opposite from lens 14. Thus, solar cell 16 is a back contact solar sell, having contacts that are formed on the back of the silicon solar cell strips. Such an arrangement ensures a low level of optical shading due to electrical wires, and results in high efficiency. The back contact 15 is a connection that may connect the cells in series or parallel, depending on the voltage output.

Because only the desirable sunlight component 40 is concentrated and focused onto the back contact solar cell 16, zero, or at least a reduced portion of desirable component 40 of sunlight 10 passes through the lens 14 is unused. Instead, all of the sunlight, or in another embodiment substantially all (i.e. >99%) of the sunlight, from the desirable component 40 that passes through the lens 14 is concentrated and focused onto the silicon back contact solar cell 16 and is converted into electrical current. According to one embodiment, the inherent translucency of even the best quality glass slab and lens material causes some sunlight not to pass through the lens 14, causing a loss of 8 to 10% of the sunlight. However, the entire sunlight component 10 that does pass through both the glass and lens is converted into electrical current.

Similarly, more than 90% of the sunlight that is not part of the sunlight component 10 is directed away from the back contact solar cell 16. The following figures will better explain how non-visible sunlight is focused away from the back contact solar cell 16 and either reflected away, concentrated and focused onto another area, or transformed to light having a wavelength range falling within that of the sunlight component 10. In these cases, the lens 14 according to one embodiment accomplishes the same efficiencies with other sunlight components as just described in relation to the sunlight component 10.

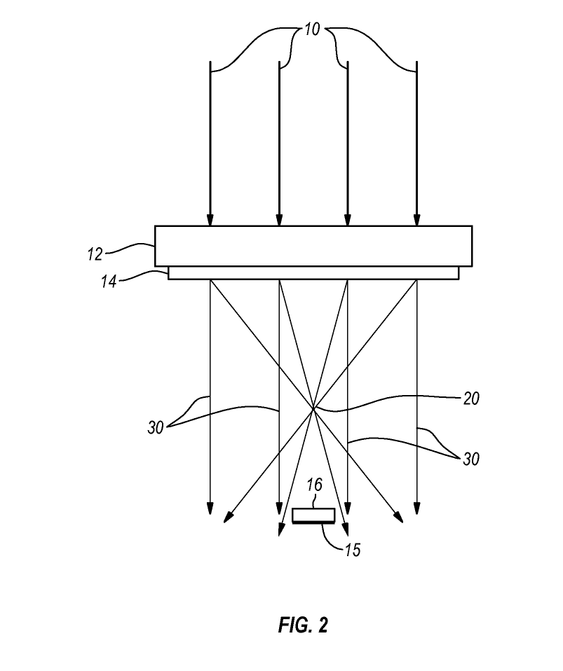

FIG. 2 represents the manner by which an undesirable sunlight component 20 is of sunlight 10 is focused so that light having undesirable wavelengths 20 does not impinge onto the silicon back contact solar cell 16 according to an exemplary embodiment of the present disclosure. Undesirable light 20 in this respect is light having wavelengths outside of the visible spectrum. More preferably, undesirable light in this respect is light having wavelengths greater than 750 nm. While the visible sunlight component 40 is bundled and captured by way of deflecting, concentrating, and focusing it on the silicon back contact solar cell 16, the undesirable light component 20 passes through the glass slab 12 and the holographic deflecting lens 14 supported thereon, which is adapted to bend and deflect the undesirable light component 20 away from the cell 16.

As depicted in FIG. 2, the deflecting characteristic of the lens 14 causes the undesirable light component 20 to do two things. On one hand, much or most of the light from the undesirable light component 20 passes straight through the structure so it does not impinge on the silicon back contact solar cell 16. On the other hand, a smaller part of the light from the undesirable light component 20 is focused, but the focus is directed to a position away from the cell 16. According to an exemplary embodiment, infrared light is focused between the silicon back contact solar cell 16 and the holographic deflecting lens 14. After reaching their focal point, the infrared light rays form a divergent bundle, with the result that at the board level, on which the silicon back contact solar cell 16 is fixed, the rays are very disperse. Consequently, the undesirable light component 20, including infrared light, is focused away from the silicon photovoltaic cell 16 such that very little if any of the light from the undesirable light component 20 impinge on the cell 16.

The undesirable light component 20 may be reflected by way of mirrors adjacent to the cell 16. However, as will be described in detail, in a preferred embodiment of the disclosure the infrared light from the undesirable light component 20 is bent and deflected by the holographic deflecting lens 14 in a manner whereby it is focused onto a germanium-coated silicon solar cell or germanium thermophotovoltaic cell that is part of a system adapted to convert heat differentials to electricity via photons. The germanium-coated silicon solar sell or germanium thermophotovoltaic cell may also be a back contact solar cell. One or more other cell materials may also be used for the cell, such as GaAs, CdS, and CdSe instead of or together with Ge.

Accordingly, the holographic deflecting lens 14 is uniquely adapted to selectively concentrate, deflect, and focus different components 40, 20 of the solar spectrum. For purposes of clarification, it is to be understood that the lens 14 is a hologram that selectively bends each different light component 40, 20 differently according to the wavelengths of light that are included in that light component. More particularly, the structures that compose the lens 14 are formed and adapted with precision to produce both an angle of deflection and a deflection efficiency that depend on the wavelength of sunlight 10 impinging on the lens 14. This enables the need for a minimal amount of silicon and other back contact solar cell material while producing high amounts of electrical energy.

According to one embodiment, the impinging sunlight 10 also includes undesirable light 30 that includes wavelengths in the ultraviolet range. In this embodiment, the holographic deflecting lens 14 is adapted to treat ultraviolet light having wavelengths below about 380 nm, and preferably including light having wavelengths below about 500 nm, in a somewhat similar manner as the infrared light discussed previously. On one hand, much or most of the ultraviolet light from the undesirable light component 30 runs straight through the structure so it does not impinge on the silicon back contact solar cell 16. On the other hand, a smaller part of the ultraviolet light from the undesirable light component 30 is focused, but the focus is again directed to a position away from the cell 16. According to an exemplary embodiment, ultraviolet light is focused beyond the silicon back contact solar cell 16 with the result that at the board level, on which the silicon back contact solar cell 16 is fixed, the rays are disperse. Consequently, the undesirable light component, including ultraviolet light 30, is focused away from the silicon photovoltaic cell 16 such that very little if any of the light from the undesirable light component 30 impinge on the cell 16.

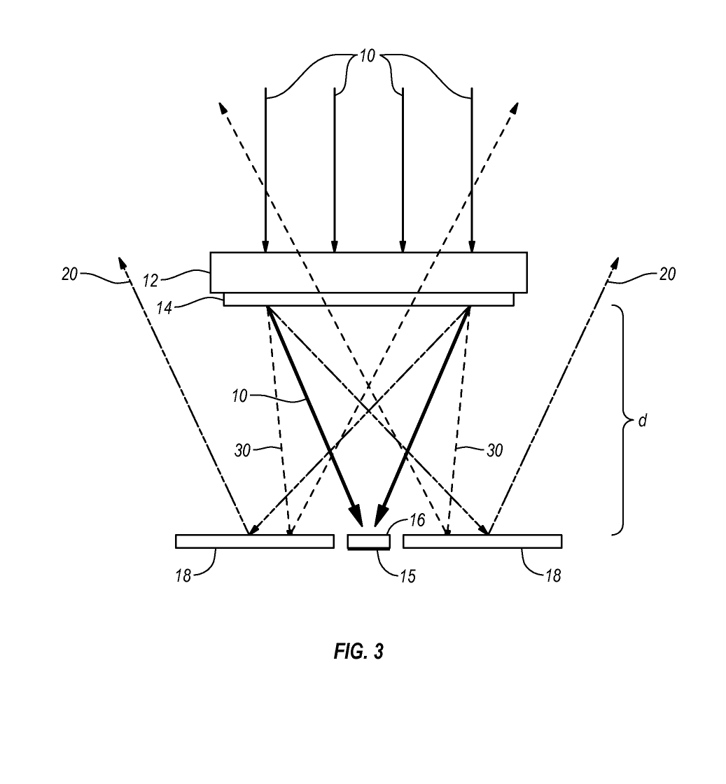

Turning now to FIG. 3, a schematic diagram is used to represent the manner by which desirable and undesirable wavelengths of sunlight are respectively focused with high efficiency onto the back contact solar cell 16, or focused away from the back contact solar cell 16 and reflected away from the solar module according to this embodiment. As depicted, the desirable light 10 is bent and focused onto the back contact solar cell 16. At the same time, the undesirable light including infrared light 20 (designated by the • • — pattern) and the ultraviolet light 30 (designated by the - - pattern) are respectively focused before and after the back contact solar cell 16 in order to avoid impinging on the cell 16.

To ensure that the light rays from the undesirable light component 20, 30 are reflected away from the cell 16, a mirror element 18 including a unique assembly of mirrors is utilized. The mirror element 18 includes a mirror coating that is preferably formed adjacent to the cell 16. According to one embodiment, the mirror coating is one layer, or a plurality of layers formed on the same board on which the back contact solar cell 16 is fixed. The mirror element may be formed from any suitable light reflective material such as copper, tin, or tin-plated copper.

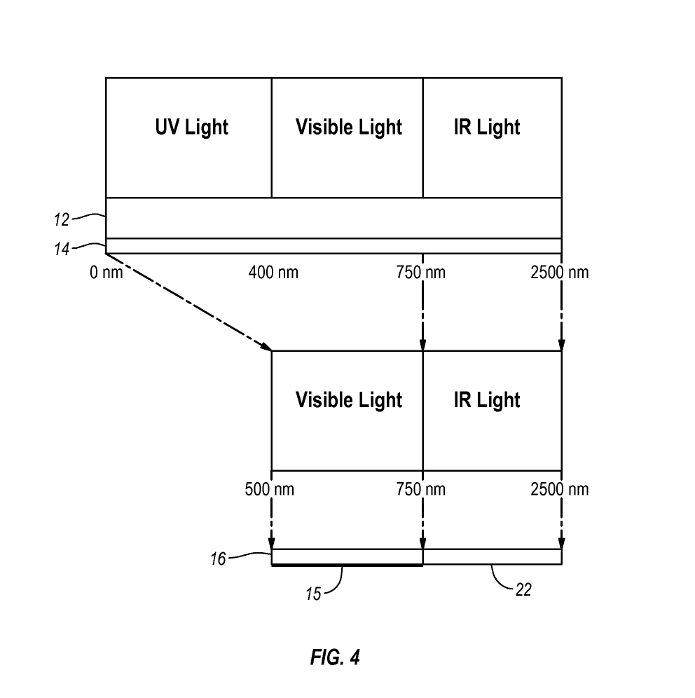

Next, another alternative embodiment will be discussed in which undesirable light including ultraviolet light 30 is not reflected away from the back contact solar cell 16 as depicted in FIGS. 2 and 3, but rather is transformed into light having desirable wavelengths. FIG. 4 is a schematic diagram representing the manner by which some undesirable wavelengths of sunlight are transformed to desirable wavelengths of light, and then the remaining wavelengths of light are selectively focused with high efficiency onto different back contact solar cells according to their wavelengths.

As depicted in FIG. 4, the visible part of the sunlight spectrum, and preferably the light with wavelengths between about 400 and about 750 nm, passes through the glass 12 and is bent by the holographic deflecting lens 14. This visible light is focused onto the silicon back contact solar cell 16 in the manner previously explained.

Also mounted on the same board as the silicon back contact solar cell 16 is a germanium thermophotovoltaic cell 22. One or more other cell materials may also be used such as GaAs, CdS, and CdSe instead of or together with Ge.

According to one embodiment, the invisible light with higher wavelengths above 750 nm, including infrared light, is not bent. Rather, the infrared light passes through the glass 12 and the holographic deflecting lens 14 formed thereon and the heat from the higher wavelength light is converted by the germanium (or other suitable material) thermophotovoltaic cell 22 into electrical current. Through the usage of a germanium cell the heat is used instead of being wasted and the efficiency of a solar module, employing the back contact solar cell and the thermophotovolatic cell 22, as a whole is increased.

According to another embodiment, the invisible light 30 with higher wavelengths above 750 nm, including infrared light 20, is deflected so that it is focused on the thermophotovoltaic cell 22. The holographic deflecting lens 14 is adapted to focus the higher wavelength light away not only away from the back contact solar cell 16 as depicted in FIGS. 2 and 3, but to also focus such light onto the thermophotovoltaic cell 22 in order to use the solar light to the maximum efficiency.

The optimal light wavelength area using a silicon back contact solar cell is from 500 nm to 750 nm. To optimize the electricity output from a silicon back contact solar cell, the holographic deflecting lens 14 is structurally adapted to transform light. The shorter wavelengths of sunlight, including ultraviolet light, are transformed into the optimal light wavelength area of 500 nm to 750 nm when passing through the holographic deflecting lens 14.

Back contact solar cell 16 may be a metal wrap through (MWT) solar cell or an interdigitated back contact (IBC) solar cell. Both types of solar cells are possible to use in the solar module.

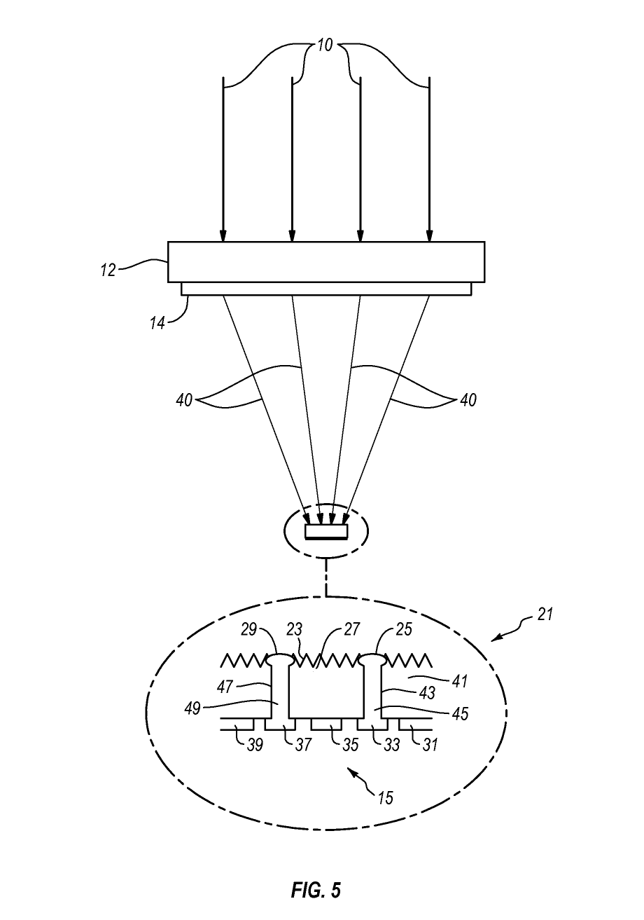

As shown in FIG. 5, the metal wrap through (MWT) solar cell 21 having contacts for the electrical interconnection on the back of the solar cell, on the side of the solar cell opposite from the glass slab 12 and lens 14. Therefore, the front contacts 25, 29, which are formed on passivated surface 23 facing toward lens 14, are connected to the back contacts, in this example, n-type contacts 33, 37, by metalized conductors 45, 49, formed in via holes 43, 47, respectively. Although passivated surface 23 is shown with periodic corrugations, the surface passivation is not limited to nor does it require periodic corrugations, and may include other means of surface passivation, such as laminate films formed thereon having differing reflectivity characteristics. Via holes 43, 47 are formed through p-type silicon base 41. In this embodiment, p-type contacts 31, 39 are also formed on the back surface of solar cell 16.

In result the MWT solar cell 21 has an advantage in efficiency due to reduced optical shading on the front of the solar cell 16, while the production cost are not higher compared to standard solar cells. The interconnection with the solar module can be realized with structured cell connectors or conductive back foils.

MWT cells with high efficiency are a viable solution provided that the stresses caused by drilling the via holes to the silicon do not cause extensive cracking or stress that prevent the cutting process.

In this example, each cell is 156×156 mm and has a minimum of 60 via holes and possibly up to 400 via holes. The hole-size has to be very small (100 um) and the stresses caused by drilling the vias are kept to the minimum to enable cutting of the cells.

Further, the pad size and feature alignment has to be small enough to ensure a low level of optical shading and in result high efficiency.

A MWT-PERC (Passivated Emitter Rear Contact) cell would give 1-2% (absolute) higher efficiency and the cell should have a development path to enable that in the future.

The metallization should not continue from one sub-cell to the next. The front metallization grid should be double-printed to have sufficient amount of metal to carry the current with low ohmic losses.

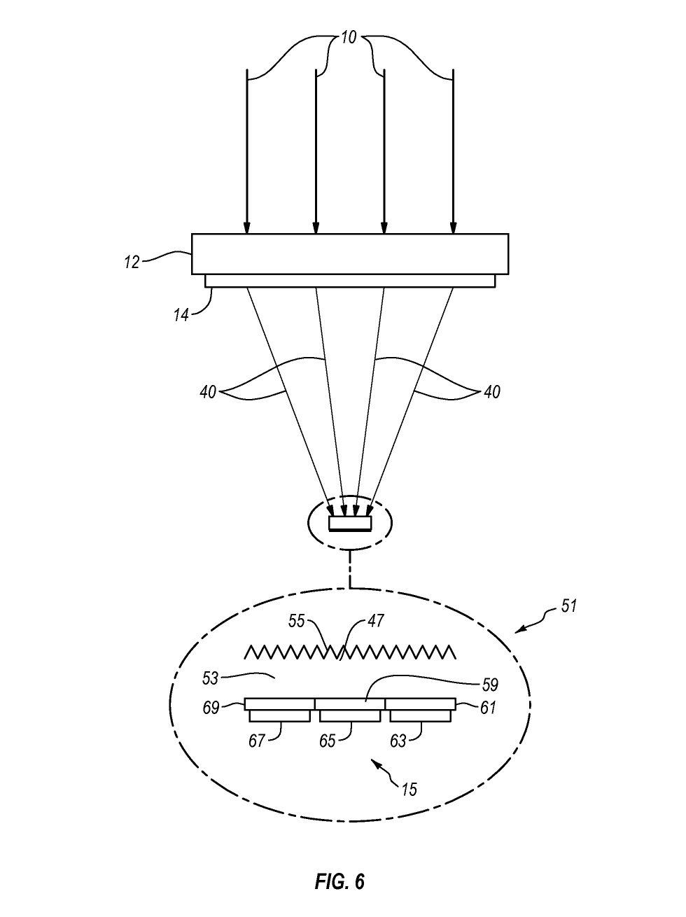

As shown in FIG. 6, solar cell 16 includes interdigitated back contact (IBC) solar cell 51, having passivated layer 55 having anti-reflection coatings formed on the surface facing toward glass slab 12 and lens 14. An n-type diffusion layer 47 is formed on p-type substrate 53 along the passivated layer 55. In the IBC solar cell, back contact 15 includes positive contact 65 formed on the surface of the solar cell opposite from the passivated surface 55. Positive contact 65 is aligned with p-type diffusion layer 59. Also on the back surface of solar cell 16, back contact 15 further includes negative contacts 63, 67, which are aligned with n-type diffusion regions 61 and 69.

Rear contact solar cells, such IBC, eliminate shading losses altogether by putting both contacts on the rear of the cell. By using a thin solar cell made from high quality material, electron-hole pairs generated by light that is absorbed at the front surface can still be collected at the rear of the cell. Such cells are especially useful in concentrator applications where the effect of cell series resistance is greater.

An additional benefit is that cells with both contacts on the rear are easier to interconnect and can be placed closer together in the module since there is no need for a space between the cells.

Although in the exemplary embodiments, semiconductor conductivity types are describes, such are arrangements are not to be limiting, and differing conductivity type arrangements may also be employed.

IBC (Interdigitated Rear Contact) cell suits very well for solar module including the lens 14 arranged between the glass slab 12 and solar cell 12. In this type of cell both contacts are on the back of the cell. The contacts are lines, should have a small pitch (about 0.5 mm) and the contacts at both ends of the 78 mm long cell.

In this example, each unit cell is separated. The metallization should be stress free to ensure easy processing of the strips. The metallization should have sufficient amount of metal to carry the current with low ohmic losses. Ion implantation is recommended for the doping to ensure good tolerances.

In this and all embodiments of the disclosure, the glass slab 14 is preferably of a thickness ranging between 0.2 and 0.6 cm. More preferably, the glass slab 14 is about 0.3 cm in thickness.

As mentioned previously, the novel holographic deflecting lens 14 makes possible a solar module in which a very small distance is needed between the lens 14 and any of the silicon cells and thermophotovoltaic cells. This distance d is depicted in FIG. 3, but applies to all embodiments discussed herein. The distance d between the lens 14 and the back contact solar cell 16 (and any thermophotovoltaic cell) may range between 0.4 cm and 5.0 cm, depending on the concentration factor. According to one embodiment, distance d can range between 1.0 cm to 5.0 cm, depending on the concentration factor. According to another embodiment, the distance d may be no greater than 1.1 cm, and preferably no greater than 0.5 cm. The distance d according to another embodiment ranges between 0.4 cm and 1.1 cm, preferably between 0.5 and 1.0 cm, and most preferably between 0.5 cm and 0.7 cm. This in turn imparts a very small overall module height and cost friendly production. Consequently, compared to traditional solar panels, a significantly reduced cost of constructing and transporting is achieved.

As mentioned previously, the holographic deflecting lens 14 is uniquely adapted to selectively concentrate, deflect, and focus different components of the solar spectrum. As also just discussed, the same lens 14 is uniquely adapted to selectively transform some light components from lower wavelength light, including ultraviolet light, into a particular range of visible light wavelengths.

The holographic lens 14 is a single-layered system with very fine lens structures that are adapted with precision to selectively bend and/or transform each different light component according to the wavelengths of light that are included in that light component. This not only enables the need for a minimal amount of silicon and other back contact solar cell material to produce high amounts of electrical energy, but the single-layered nature of the holographic deflecting lens 14 also imparts simple duplicability to the lens as a whole. Conventional holographic grids are manufactured by repeated steps of coating, exposing, and developing films or foils. The foils are laminated to a holographic foil cluster, and in a conventional system four or more foils are laminated to one foil. This manufacturing method is expensive because it requires a lot of machinery and is extremely slow.

In contrast, the holographic deflecting lens 14 is preferably a printed hologram that is a grid structure, but differs from a holographic grid, which has to be costly exposed with each manufacture as described above. Instead, the deflecting surface release structure of the present disclosure can be repeatedly duplicated almost any number of times. This new method includes printing the hologram on the glass 12 of the module in a roll-to-roll process. In another embodiment, the hologram may be printed on the glass in a roll-to-place process. The hologram is preferably printed, and more preferably using a polymer material, in one single printing step. Furthermore, the hologram is a single layer that is printed in one simple rolling print process. It is not necessary to coat, expose and/or develop the foil. Because of the simplicity and the single print rolling step nature of this method, the holographic deflecting lens 14 can be replicated on the inner side of the glass slab 12.

The holographic deflecting lens 14 may be made from silicone or a hardened UV-glue or UV lacquer or Polymethylmethacrylate (PMMA). The production of a foil, which has the surface relief on one side, is also possible due to the nature of the lens 14. The foil may also be affixed on the glass 12 or laminated thereon. Accordingly, the glass 12 can function as support material for the holographic deflecting lens 14 and it protects the lens 14 from destructive environmental influences.

It is of value to next explain some other advantages of the present solar modules when compared to conventional systems that incorporate Fresnel lenses. Sunlight in all of its wavelengths is broken and magnified many hundreds of times with a Fresnel lens without selectivity of any particular wavelengths. Because even infrared light and ultraviolet light are broken and magnified, several disadvantages are inherent in Fresnel lens modules. The heat created by magnification of all of the sunlight wavelengths, including infrared light, creates an enormous amount of heat. Consequently, conventional solar modules must be equipped with some sort of cooling system to avoid early wear and destruction of the solar module components including the semiconductor material, as well as the solar panel as a whole. Furthermore, a Fresnel lens has a relatively large focal length of up to 20 cm, and this in turn produces modules that are quite thick. These large structures result in solar power units that are very heavy.

In contrast, the solar modules of the present disclosure treat different sunlight components differently according to the wavelengths of light included in each component. Exemplary solar modules according to one embodiment of the present disclosure include the holographic deflecting lens 14 that is adapted to bend and concentrate a selected component of visible light having a specific wavelength range, preferably ranging between 500 and 600 nm, and more preferably ranging between 510 and 580 nm, and concentrate that light onto the back contact solar cell 16. Thus, because the light is bent and concentrated instead of being broken and magnified with a Fresnel lens, the distance d between the lens 14 and the back contact solar cell 16 may be between 0.4 to 5.0 cm, depending on the concentration factor. In one embodiment, distance d may range from 1.0 to 5.0 cm, depending on the concentration factor. In another embodiment, distance d may range from 0.4 cm to 0.5 cm, depending on the concentration factor.

Furthermore, because the higher frequency light component, including infrared light, is either reflected away from the back contact solar cell 16 according to one embodiment, or is selectively bent and concentrated onto a thermophotovoltaic cell according to another embodiment, using the same holographic lens 14, no cooling structure needs to be included in the solar module of the present disclosure.

Finally, because the lower frequency light component, including ultraviolet light, is either reflected away from the back contact solar cell 16 according to one embodiment, or is transformed into visible light of the preferred wavelength range according to another embodiment, it is possible to produce electricity from essentially the entire sunlight spectrum with a single holographic lens 14 without any Fresnel lens, any additional holographic lens, or any other lenses of any type included in the solar module. In other words, the solar module is a single-lens system in which the only lens that is used is the deflecting holographic lens 14 that is directly fixed on and supported by the glass slab 12. Furthermore, a solar module incorporating such back contact solar cells consists of the single-lens holographic lens 14.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure, it being understood that various changes may be made in the function and arrangement of elements described in an exemplary embodiment without departing from the scope of the disclosure as set forth in the appended claims and their legal equivalents.

What is claimed is:

1. An energy conversion device comprising:
a holographic lens arranged between a glass slab and the first solar cell, wherein
the holographic lens is configured to concentrate a portion of a first component of impinging electromagnetic radiation onto the first solar cell and direct a portion of a second component of the electromagnetic radiation away from the first solar cell, and
the first solar cell is a back contact solar cell configured to convert the first component of the electromagnetic radiation into electrical energy.

2. The energy conversion device according to claim 1, wherein the first solar cell includes at least one solar cell stripe arranged between the holographic lens and an electrical connector, the electrical connector being electrically connected to the at least one solar cell stripe.

3. The energy conversion device according to claim 1, wherein the first solar cell is a metal wrap through (MWT) solar cell.

4. The energy conversion device according to claim 1, wherein the first solar cell is an interdigitated back contact (IBC) solar cell.

5. The energy conversion device according to claim 1, wherein the holographic lens is formed directly on the glass slab.

6. The energy conversion device according to claim 1, wherein
the holographic lens is a single-layer holographic lens.

7. The energy conversion device according to claim 1, wherein
the first component of the electromagnetic radiation includes visible light, and
the second component of the electromagnetic radiation includes at least one of infrared light and ultraviolet light.

8. The energy conversion device according to claim 1, wherein
the holographic lens includes a hologram printed onto the glass slab.

9. The energy conversion device according to claim 8, wherein
the hologram includes a polymer material printed onto the glass slab.

10. The energy conversion device according to claim 1, further comprising
a second solar cell arranged at a position different than the first solar cell,
wherein the holographic lens is configured to concentrate the portion of the second component of the electromagnetic radiation onto the second solar cell, and
wherein the first solar cell is photovoltaic cell, and the second solar cell is a thermophotovoltaic cell.

11. The energy conversion device according to claim 1, wherein
the holographic lens is configured to focus the portion of the second component of the electromagnetic radiation at a first position that is away from the first solar cell, the first position being between the holographic lens and the first solar cell.

12. The energy conversion device according to claim 1, wherein
the holographic lens is configured to focus the portion of the second component of the electromagnetic radiation at a second position that is away from the first solar cell, the second position being on a side of the first solar cell opposite from the holographic lens.

13. The energy conversion device according to claim 1, wherein
the holographic lens is separated from the first solar cell by a distance that is no greater than 5.0 cm.

14. The energy conversion device according to claim 1, wherein
the first component of the electromagnetic radiation consists of visible light in the range of 500 nm to 600 nm.

15. The energy conversion device according to claim 1, wherein
the energy conversion device is entirely devoid of a cooling system.

16. The energy conversion device according to claim 1, wherein
the first solar cell includes silicon.

17. The energy conversion device according to claim 10, further comprising
a mirror element configured to reflect at least some of the portion of the second component of the electromagnetic radiation toward the second solar cell.

18. The energy conversion device according to claim 1, wherein
the second component of the electromagnetic radiation includes ultraviolet light, and
the holographic lens is configured to transform a portion of the ultraviolet light into light having a wavelength similar to the first component of the electromagnetic radiation and deflect the light having the wavelength similar to the first component of the electromagnetic radiation onto the first solar cell.

19. An energy conversion device comprising:
a holographic lens arranged between a glass slab and the first solar cell, wherein
the holographic lens is configured to concentrate a portion of a first component of impinging electromagnetic radiation onto the first solar cell and direct a portion of a second component of the electromagnetic radiation away from the first solar cell,
the holographic lens is a single-layer holographic lens including a holograph printed onto the glass slab, the holograph including a polymer material,
wherein the first component of electromagnetic radiation includes visible light, and the second component of electromagnetic radiation includes at least one of infrared light and ultraviolet light, and
the first solar cell is a back contact solar cell including at least one solar cell stripe arranged between the holographic lens and an electrical connector, the first solar cell being configured to convert the first component of the electromagnetic radiation into electrical energy.

20. A method of making an energy conversion device, the method comprising:
roll printing a hologram directly onto a glass slab in a pattern that forms a holographic lens;
arranging the holographic lens between the glass slab and a first solar cell; and
arranging the first solar cell such that at least one solar cell stripe of the first solar cell is arranged between the holographic lens and an electrical connector, the electrical connector being electrically connected to the at least one solar cell stripe.
